(19) United States
(12) Patent Application Publication
(10) Pub. No.: US 2026/0319380 A1
(43) Pub. Date: Oct. 15, 2026

(54) METHOD FOR ADJUSTING AT LEAST ONE SENSOR FOR A PROJECTION EXPOSURE APPARATUS AND PROJECTION EXPOSURE APPARATUS

(71) Applicant: Carl Zeiss SMT GmbH, Oberkochen (DE)

(72) Inventors: Ulfert WIESENDAHL, Oberkochen (DE); Marcel TESCHKE, Oberkochen (DE); Christoph FETZER, Oberkochen (DE); Matthias ABEND, Oberkochen (DE)

(21) Appl. No.: 19/687,672

(22) Filed: May 26, 2026

Related U.S. Application Data
(63) Continuation of application No. PCT/EP2024/083911, filed on Nov. 28, 2024.

(30) Foreign Application Priority Data
Nov. 28, 2023 (DE) 10 2023 211 839.4

(51) Int. Cl. G03F 7/00

(52) U.S. Cl. CPC G03F 7/70591; G03F 7/70258; G03F 7/705

(57) ABSTRACT

A method adjusts at least one sensor for a projection exposure apparatus.

### CROSS-REFERENCE TO RELATED APPLICATIONS

The present application is a continuation of, and claims benefit under 35 USC 120 to, international application No. PCT/EP 2024/083911, filed Nov. 28, 2024, which claims benefit under 35 USC 119 of German Application No. 10 2023 211 839.4, filed Nov. 28, 2023. The entire disclosure of each of these applications is incorporated by reference herein.

### FIELD

The present disclosure relates to a method for adjusting at least one sensor for a projection exposure apparatus, comprising: a) providing at least one primary sensor and at least one optical module for a projection exposure apparatus, at least one measurement reference being arranged on the optical module, the primary sensor being configured to detect a change in the position and/or the orientation of the optical module and/or the measurement reference and/or the primary sensor being configured to detect the position and/or the orientation of the optical module and/or the measurement reference; b) performing a measurement using the primary sensor, the optical module being moved, for example displaced, tilted and/or rotated, relative to the primary sensor and/or the primary sensor being moved, for example displaced, tilted and/or rotated, relative to the optical module during the measurement; and c) performing a final adjustment of the primary sensor using the measurement performed in step b), the primary sensor being arranged in a final position and/or a final orientation. The present disclosure furthermore relates to a projection exposure apparatus comprising: at least one primary sensor and at least one optical module.

### BACKGROUND

Microlithography is used for producing microstructured components, such as for example integrated circuits. The microlithography process is performed for example using a projection exposure apparatus, which inter alia comprises an illumination optical unit and/or a projection optical unit. The structure of a mask (reticle) illuminated via the illumination optical unit is projected here via the projection optical unit onto a substrate, for example a wafer, for example silicon wafer, which is coated with a light-sensitive layer (photoresist) and arranged in the image plane of the projection optical unit, in order to transfer the mask structure to the light-sensitive coating of the substrate.

One of the aims in the development of projection exposure apparatuses is to lithographically produce structures having smaller and smaller dimensions on the substrate, for example to obtain greater integration densities in semiconductor components. One approach involves working with shorter wavelengths of electromagnetic radiation. For example, optical systems have been developed which use electromagnetic radiation from the so-called “deep ultraviolet” (DUV) range, such as with operating wavelengths in the range between 150 nm and 400 nm, for example 365 nm, 248 nm or 193 nm, or from the extreme ultraviolet (EUV) range, such as with operating wavelengths in the range between 5 nm and 30 nm, for example at 13.5 nm.

In order to create the structures on the substrate with the highest possible accuracy and thus maximize the yield during the microlithography process, it is typically desirable to align the various components of the projection exposure apparatus as precisely as reasonably possible, and also typically desirable to determine the position and/or orientation of certain components of the projection exposure apparatus, for example of the optical modules of the projection exposure apparatus, as precisely as reasonably possible. In general, precise correction of aberrations is difficult, or not possible at all, without precise knowledge of the position and/or orientation of certain components, for example of the optical modules and optical elements.

In order to determine the position and/or orientation of the optical modules of the projection exposure apparatus, a projection exposure apparatus often comprises a plurality of primary sensors, which are used for example for determining the position and/or orientation of the optical modules or for determining the change in the position and/or the orientation of the optical modules. A single optical module is often assigned multiple such primary sensors. In the course of the production of a projection exposure apparatus and the first installation of an optical module or in the course of an exchange of an optical module, especially after a certain operating time of the projection exposure apparatus, it is usually desirable to adjust the primary sensors for the optical module which are assigned to the respective optical module. Precise adjustment makes it easier, and, in many cases, even makes it possible, to possibly perform a precise measurement via the respective primary sensor.

The respective primary sensor can be adjusted on the basis of a target position and target orientation of the respective primary sensor, wherein this target position and target orientation were determined in advance during the development and design of the projection exposure apparatus. However, manufacturing tolerances, deformations and external influences that can affect both the primary sensor itself and other components of the projection exposure apparatus are often ignored during an adjustment to such a target position and target orientation. This often renders a best possible adjustment of the primary sensor difficult or impossible. It may be the case that the sensor is not pre-adjusted to a satisfactory level, for example by the sensor manufacturer.

### SUMMARY

The present disclosure seeks to provide a method of adjusting at least one sensor for a projection exposure apparatus and a projection exposure apparatus, each of which provide a best possible alignment of the primary sensor.

In an aspect, the disclosure provides a method of adjusting at least one sensor for a projection exposure apparatus. In this context, the method comprises the following step: a) providing at least one primary sensor and at least one optical module for a projection exposure apparatus. The optical module can comprise at least one optical element, for example at least one lens element and/or at least one mirror. The optical module is provided to influence and/or guide exposure radiation of the projection exposure apparatus. The exposure radiation is the radiation created by the radiation source of the projection exposure apparatus and/or provided for the exposure of a substrate to be arranged in the projection exposure apparatus. The primary sensor can be a separate component from the optical module. In the mounted state, for example when mounted on at least one frame of a projection exposure apparatus, the primary sensor is at a distance from the optical module.

Provision can also be made for at least one measurement reference to be arranged on the optical module. The measurement reference can interact with the primary sensor during a measurement and simplifies the measurement, in some cases even allows the measurement, since the measurement reference provides a reference, especially a unique reference, for the measurement. For example, the measurement reference can be configured as a measuring surface and/or a measuring grid. The measurement reference can be a constituent part of the optical module or a separate component. Optionally, the measurement reference is fixedly and/or rigidly connected, for example adhesively bonded, to the optical module.

Provision can also be made for the primary sensor to be configured to detect a change in the position and/or the orientation of the optical module and/or the measurement reference and/or for the primary sensor to be configured to detect the position and/or the orientation of the optical module and/or the measurement reference. The exact position and/or orientation of the optical module can be determined as a result, for example during the operation of a projection exposure apparatus, and precise changes in the position and/or orientation of the optical module can be performed on the basis thereof, in order to correct aberrations. In addition, a measurement using the primary sensor can be used to adjust the primary sensor itself. The primary sensor can detect the change in the position and/or the orientation of the optical module and/or the measurement reference in absolute terms and/or relative to the primary sensor. In an alternative to that or in addition, the primary sensor can detect the position and/or the orientation of the optical module and/or the measurement reference in absolute terms and/or relative to the primary sensor. The detection is for example a measurement of the changes in the position and/or the orientation of the optical module and/or the measurement reference, and/or a measurement of the position and/or the orientation of the optical module and/or the measurement reference.

In addition, the method comprises the step: b) performing a measurement via the primary sensor, the optical module being moved, for example displaced, tilted and/or rotated, relative to the primary sensor and/or the primary sensor being moved, for example displaced, tilted and/or rotated, relative to the optical module during the measurement. Performing the measurement in step b) can comprise the capture and/or storage of at least a portion of the measurement signal, for example the entire measurement signal, of the primary sensor. The measurement signal can comprise the signal curve of the amplitude, the phase and/or the offset. The final position and/or final orientation of the primary sensor, hence for example an optimal position and/or orientation of the primary sensor, can be determined precisely in a simple manner by way of the measurement performed while moving, for example by way of the measurement signal of the primary sensor captured when moving, and for example the information about the position and/or orientation of the optical module and/or the primary sensor while moving. This can be because the primary sensor can for example be arranged in the position and/or orientation in which the measurement signal, for example the amplitude of the measurement signal, of the primary sensor is as high as reasonably possible, for example substantially at a maximum, when the optical module is in its basic position and/or basic orientation. In some cases, an optimal adjustment can involve the phase and/or the offset of the measurement signal to also be located within a tolerance range. The basic position and/or basic orientation can the position and/or orientation of the optical module in which the optical module is located in its zero position, for example when mounted in a projection exposure apparatus. Even if only the optical module is moved in step b), the final position and/or final orientation of the primary sensor can be determined precisely since use of the information captured in step b) about the position and/or orientation of the optical module while the optical module is moved allows conclusions to be drawn about the best possible position and/or orientation of the primary sensor. When the optical module is moved relative to the primary sensor, the measurement reference can also be moved relative to the primary sensor, for example in a manner corresponding to the optical module. The position and/or orientation of the optical module can be controlled, regulated and/or detected in step b). At least one secondary sensor can be used for detection. For example, the at least one secondary sensor is the at least one secondary sensor that will still be discussed below. Provision can be made for the primary sensor to detect the change in the position and/or the orientation of the measurement reference in step b) and/or for the primary sensor to detect the position and/or the orientation of the measurement reference in step b). While the optical module is moved relative to the primary sensor, provision can be made for the primary sensor to be not moved and/or be stationary. In an alternative to that or in addition, provision can be made for the optical module to be not moved and/or be stationary while the primary sensor is moved relative to the optical module. Provision can be made for the optical module and/or the primary sensor to be moved, for example substantially completely, along at least one, such as at least two, for example at least three, translational degrees of freedom and/or at least one, such as at least two, for example at least three, rotational degrees of freedom of the optical module and/or the primary sensor in step b), optionally during the measurement and/or in a manner mounted in a projection exposure apparatus. This facilitates determination of the final position and/or final orientation of the primary sensor since the measurement signal is captured during step b) for substantially the entire adjustment range of the optical module and/or the primary sensor. Provision can be made for the optical module and/or the primary sensor to be moved at least temporarily, for example substantially completely, in succession and/or at the same time along at least two translational and/or rotational degrees of freedom. A movement along at least one translational degree of freedom can be a movement along the X-axis, Y-axis and/or Z-axis. A movement along at least one rotational degree of freedom can be a movement, for example rotation, about the X-axis, Y-axis and/or Z-axis. The X-axis, Y-axis and Z-axis in this case form a Cartesian coordinate system. The Z-axis can extend at least in sections through the primary sensor, the measurement reference and/or the optical module. Optionally, the X-axis and/or the Y-axis are in a plane with the measurement reference. The X-axis and/or the Z-axis can correspond to the measurement direction of the primary sensor. The optical module and/or the primary sensor can be moved along the Z-axis, rotated about the X-axis and/or rotated about the Y-axis during step b), for example during the measurement via the primary sensor. Other or further movements along and/or about the respective axes are also possible but depend at least in part on the type of primary sensor to be adjusted.

In addition, the method comprises the step: c) performing a final adjustment of the primary sensor using the measurement performed in step b), the primary sensor being arranged in a final position and/or a final orientation. As a result, the sensor can be arranged in a position and/or orientation that is as optimal as reasonably possible. In step c), the primary sensor can for example be adjusted relative to a frame of the projection exposure apparatus, for example the sensor frame and/or the force frame, the optical module and/or the measurement reference. For example, an adjustment relative to the sensor frame can be implemented. The arrangement in the final position and/or final orientation can be implemented in various ways, for example by arranging or replacing a final alignment element. The primary sensor can be arranged on at least one frame of a projection exposure apparatus in step c), for example on the sensor frame and/or force frame of a projection exposure apparatus. For example, step c) is implemented after step a) and/or after step b).

The sensor frame within the meaning of the present disclosure is a structure that does not take part substantially in the static or dynamic loads that act on the components of the projection exposure apparatus. The sensor frame thus substantially carries only itself and the components desired for the sensor system, for example the at least one primary sensor and/or the at least one secondary sensor. Typically, the sensor frame is largely decoupled in mechanical terms from the rest of the structure of the projection exposure apparatus and thus constitutes a reliable reference for determining the positions and/or orientations of the components involved. The force frame is understood to be the mechanical support structure of the optical module, for example of all optical modules. Firstly, the force frame absorbs the static loads, which for example originate from the gravitational force acting on the optical modules involved; secondly, the force frame also absorbs dynamic loads, for example from positioning and/or orientation movements of the optical modules.

The “orientation” of an object, such as a component or an assembly, is understood within the scope of the present application to mean the angular position of the component or the assembly with respect to one or more independent axes of rotation; by contrast, the “position” should be understood to mean the arrangement of the component or the assembly along independent spatial directions of a coordinate system.

One embodiment of the method provides for the optical module and/or the primary sensor to be moved in step b) via at least one manipulator, for example of a projection exposure apparatus. This can help allow relatively precise movement of the optical module and/or the primary sensor. In addition, as a result, additional equipment can be omitted or at least the equipment can be reduced, where applicable, for the movement in step b) since for example the optical module is already connected to manipulators in the mounted state in a projection exposure apparatus. The at least one manipulator can be at least one manipulator arranged in a projection exposure apparatus and/or manipulator provided for manipulation of the optical module and/or of the primary sensor, for example during the operation of the projection exposure apparatus.

In the present case, the term “manipulator” preferably refers to optomechanical, electromechanical and/or electrical devices intended for example to actively influence individual optical elements, groups of optical elements, optical modules and/or groups of optical modules on the basis of at least one control signal in order to modify the optical effect of these elements, groups of elements, modules and/or groups of modules in the projection beam path of a projection exposure apparatus. Often, manipulators are also provided in order for example to displace, tilt and/or deform the mask and/or the substrate. In general, the manipulators are set in such a way that metrologically detected aberrations can be corrected in a targeted manner.

One embodiment of the method provides for the optical module and/or the primary sensor to be moved along at least one translational and/or rotational degree of freedom of the optical module and/or the primary sensor in step b), for example during the measurement via the primary sensor, and for, optionally, the primary sensor to have its highest measurement sensitivity along the at least one translational and/or rotational degree of freedom of the optical module and/or the primary sensor. This can help facilitate determination of the optimal position and/or orientation of the primary sensor relative to the optical module since the measurement signal is captured during step b) for at least a portion of the adjustment range of the optical module and/or the primary sensor. Then, the final position and/or final orientation for the primary sensor can be determined very precisely on the basis of this measurement signal. For example, there is a movement along the degree or the degrees of freedom along which the primary sensor should detect a position and/or orientation or a change in the position and/or orientation when a projection exposure apparatus is in operation, by virtue of there being for example a movement along the at least one degree of freedom, in which the primary sensor has its highest measurement sensitivity. This can help facilitate a precise adjustment for the most relevant degrees of freedom. In step b), the optical module can be moved out of the basic position and/or basic orientation of the optical module along at least one translational degree of freedom and/or at least one rotational degree of freedom of the optical module.

In an alternative to that or in addition, provision can be made for the optical module and/or the primary sensor to be moved in the direction of at least one maximum reachable position and/or orientation along at least one translational degree of freedom and/or at least one rotational degree of freedom of the optical module and/or the primary sensor in step b), for example during the measurement via the primary sensor, and/or for the optical module and/or the primary sensor to be situated in at least one maximum reachable position and/or orientation along at least one translational degree of freedom and/or at least one rotational degree of freedom of the optical module and/or the primary sensor in step b), for example during the measurement via the primary sensor.

For example, in the present disclosure, the maximum reachable position and/or orientation is the position and/or orientation which the optical module and/or the primary sensor can reach in the mounted state in a projection exposure apparatus, for example by being moved via at least one manipulator of the projection exposure apparatus.

One embodiment of the method provides for the method to comprise the following step: d) determining the final position and/or the final orientation of the primary sensor and/or determining at least one final alignment element for the primary sensor. Step d) can be implemented after step a), after step b) and/or before step c). Determination of the final position and/or the final orientation of the primary sensor and/or determination of at least one final alignment element for the primary sensor can be implemented automatically, at least in part, for example substantially in full, for example via a computer program, and/or can comprise a graphical evaluation, for example of the measurement signal of the primary sensor detected in step b). Corresponding alignment elements are also referred to as “spacers”. The final alignment element can be arranged on the primary sensor and/or on at least one frame of a projection exposure apparatus, for example the sensor frame, and has for example a geometry adapted to the final position and/or final orientation of the primary sensor.

One embodiment of the method provides for the final position and/or the final orientation of the primary sensor to be determined in step d) using the measurement performed in step b), for example using the measurement signal of the primary sensor during the measurement performed in step b), and/or for the final alignment element to be determined in step d) using the measurement performed in step b), for example using the measurement signal of the primary sensor during the measurement performed in step b). This can help allow for precise determination of the final position and/or final orientation of the primary sensor. In an alternative to that or in addition, provision can be made for the final position and/or the final orientation of the primary sensor to be determined on the basis of the position and/or orientation of the primary sensor and/or the optical module in step b) and/or for this to be determined on the basis of the difference between the position and/or orientation of the primary sensor and/or the optical module and the zero position of the optical module in step b), wherein, optionally, the position and/or orientation of the primary sensor and/or the optical module in step b) and/or the difference between the position and/or orientation of the primary sensor and/or the optical module and the zero position of the optical module is determined in step b) using the measurement performed in step b), for example using the measurement signal of the primary sensor during the measurement performed in step b). Determination of the final position and/or the final orientation of the primary sensor and/or determination of the final alignment element can be implemented using the amplitude, for example the maximum of the amplitude, of the measurement signal captured in step b). As already explained, this can be because the primary sensor can for example be arranged in the position and/or orientation in which the measurement signal, for example the amplitude of the measurement signal, of the primary sensor is as high as reasonably possible, for example substantially at a maximum, when the optical module is in its basic position and/or basic orientation. In some cases, an optimal adjustment can involve the phase and/or the offset of the measurement signal to be located within a tolerance range. In an alternative to that or in addition, provision can be made for the final position and/or the final orientation of the primary sensor to be determined in step d) via a virtual model. The virtual model can consider, for example comprise, at least a portion of the measurement signal, such as the entire measurement signal, of the primary sensor during the measurement performed in step b). The virtual model can consider, for example comprise, the position and/or orientation of the primary sensor and/or the optical module in step b) and/or the difference between the position and/or orientation of the primary sensor and/or the optical module and the zero position of the optical module in step b). The virtual model may comprise at least one piece of geometry information of an initial alignment element, which can be arranged on the primary sensor. The virtual model can also contain at least one piece of information, for example geometry information, about potential alignment elements, wherein the final alignment element can be selected from the potential alignment elements.

One embodiment of the method provides for the method to comprise the following step: e) determining an initial position and/or an initial orientation of the primary sensor and/or determining at least one initial alignment element for the primary sensor, the primary sensor in the initial position and/or the initial orientation being able to detect a change in the position and/or the orientation of the optical module and/or the measurement reference and/or the primary sensor in the initial position and/or the initial orientation being able to detect the position and/or the orientation of the optical module and/or the measurement reference. In order inter alia to be able to perform a measurement in step b), it is often desirable to firstly position and orient the primary sensor in such a way that a meaningful measurement, or even any measurement at all, can be performed using the sensor. Therefore, it can be desirable to first determine the initial position and/or initial orientation or an initial alignment element. Step e) can be implemented before step b), before step c) and/or before step d). The initial alignment element can be arranged on the primary sensor and/or on at least one frame of a projection exposure apparatus, for example the sensor frame, and has for example a geometry adapted to the initial position and/or initial orientation of the primary sensor.

In the present disclosure, the term “final” and the term “initial” serve only to distinguish different features, for example the final alignment element and the initial alignment element, and in principle should not be construed as limiting, especially with regard to the number and/or the order of the features described therewith, unless otherwise described in the present disclosure.

One embodiment of the method provides for the initial position and/or the initial orientation of the primary sensor to be determined in step e) using at least one piece of geometry information of the optical module, the primary sensor, the measurement reference, at least one frame of a projection exposure apparatus and/or at least one connecting element of a projection exposure apparatus and/or the initial alignment element to be determined in step e) using at least one piece of geometry information of the optical module, the primary sensor, the measurement reference, at least one frame of a projection exposure apparatus and/or at least one connecting element of a projection exposure apparatus and for, optionally, the at least one piece of geometry information to be determined via a measurement, for example using a coordinate measuring machine. This can help facilitate determination of an initial position, an initial orientation and/or an initial alignment element that are already relatively close to the final position, the final orientation and/or the initial alignment element. On the one hand, this can help facilitate detection in step b) of a good measurement signal or even a usable measurement signal of the primary sensor since this leads to the primary sensor being arranged at least in the region in which the position and/or orientation or a change in the position and/or orientation of the optical module and/or the measurement reference can be detected by the primary sensor. This moreover can frequently lead to only a minor change in the position and/or orientation of the primary sensor being used in step c). The at least one frame of a projection exposure apparatus can be the force frame and/or the sensor frame of a projection exposure apparatus. The geometry information can be determined for example via a measurement, such as a precision measurement, for example using a coordinate measuring machine, of the optical module, the primary sensor, the measurement reference, the at least one frame of a projection exposure apparatus and/or the at least one connecting element of a projection exposure apparatus.

A “connecting element” within the meaning of the present disclosure can be provided for the connection, for example active connection, and/or coupling of components of a projection exposure apparatus. The connecting element can be a separate component and/or constituent part of a component of the projection exposure apparatus. A corresponding connecting element is also referred to as an “interface”.

Geometry information within the meaning of the present disclosure can comprise at least one piece of information about the geometry, the position and/or the orientation of the respective component.

One embodiment of the method provides for the initial position and/or the initial orientation of the primary sensor to be determined in step e) via a virtual model, optionally comprising at least one piece of geometry information of the optical module, the primary sensor, the measurement reference, at least one frame of a projection exposure apparatus and/or at least one connecting element of a projection exposure apparatus, and/or for the initial alignment element to be determined in step e) via a virtual model, optionally comprising at least one piece of geometry information of the optical module, the primary sensor, the measurement reference, at least one frame of a projection exposure apparatus and/or at least one connecting element of a projection exposure apparatus. This can help facilitate detection in step b) of a good measurement signal or even a usable measurement signal of the primary sensor since a plurality of pieces of information, for example geometry information, of different components can be processed by the virtual model, and hence a precise determination of the initial position, the initial orientation and/or the initial alignment element is facilitated. The at least one frame of a projection exposure apparatus can be the force frame and/or the sensor frame of a projection exposure apparatus. The at least one piece of geometry information of the optical module, the primary sensor, the measurement reference, at least one frame of a projection exposure apparatus and/or at least one connecting element of a projection exposure apparatus for example is the at least one piece of geometry information determined via a measurement, for example using a coordinate measuring machine. The virtual model can also comprise at least one piece of information, for example at least one piece of geometry information, of further optical modules, sensors, frames of a projection exposure apparatus and/or connecting elements of a projection exposure apparatus. In an alternative to that or in addition, the virtual model can contain at least one piece of information, for example geometry information, about potential alignment elements, wherein the initial alignment element can be selected from the potential alignment elements.

One embodiment of the method provides for the method to comprise the following step: f) performing an initial adjustment of the primary sensor, the primary sensor optionally being arranged in the initial position and/or the initial orientation and/or the initial alignment element optionally being arranged on the primary sensor. In order inter alia to be able to perform a measurement in step b), it is often desirable to firstly position and orient the primary sensor in such a way that a meaningful measurement, or even any measurement at all, can be performed using the primary sensor. Therefore, an initial adjustment of the primary sensor can be desirable. In step f), the primary sensor can for example be adjusted relative to a frame of the projection exposure apparatus, for example the sensor frame and/or the force frame, the optical module and/or the measurement reference. The primary sensor can be arranged on at least one frame of a projection exposure apparatus in step f), for example on the sensor frame and/or force frame of a projection exposure apparatus. In step f), the primary sensor can be arranged in the initial position and/or initial orientation using at least one reference element, for example at least one stop element, and/or, in step f), the initial alignment element can be arranged on at least one reference element, for example at least one stop element. This facilitates the initial adjustment. Step f) is implemented for example before step b), before step c), before step d) and/or after step e).

One embodiment of the method provides for the position and/or the orientation of the primary sensor to be modified in step c), for example relative to the initial position and/or the initial orientation of the primary sensor, for the final alignment element to be arranged on the primary sensor in step c) and/or for the initial alignment element to be switched with the final alignment element in step c). This can help enable a relatively simple adjustment of the primary sensor.

One embodiment of the method provides for the method to comprise the following step: g) checking the final adjustment performed in step c), a measurement being performed using the primary sensor, and the optical module being moved, for example relative to the primary sensor. This can help ensure that the final adjustment performed in step c) has positioned the primary sensor in a best possible position and/or orientation. Step g) is implemented for example after step a), step b), step c), step d), step e) and/or step f). In step g), the optical module can be moved via at least one manipulator, for example of a projection exposure apparatus. The at least one manipulator can be at least one manipulator arranged in a projection exposure apparatus and/or manipulator provided for manipulation of the optical module, for example during the operation of the projection exposure apparatus. Therefore, additional equipment can optionally be omitted or at least the equipment can be reduced in order to move the optical module. The change in the position and/or the orientation of the optical module can be detected in step g) using the primary sensor and/or the position and/or the orientation of the optical module is detected in step g) via the primary sensor. Provision can be made for the optical module to be moved, for example substantially completely, along at least one, such as at least two, for example at least three, translational degrees of freedom and/or at least one, such as at least two, for example at least three, rotational degrees of freedom of the optical module and/or the primary sensor in step g), such as during the measurement of the primary sensor and/or in a manner mounted in a projection exposure apparatus. This facilitates a check of the final position and/or final orientation of the primary sensor since the measurement signal is captured during step g) for substantially the entire adjustment range of the optical module. Provision can be made for the optical module to be moved at least temporarily, for example substantially completely, in succession and/or at the same time along at least two translational and/or rotational degrees of freedom. Performing the measurement in step g) can comprise the capture and/or storage of at least a portion of the measurement signal, for example the entire measurement signal, of the primary sensor.

One embodiment of the method provides for the optical module to be moved in the direction of at least one maximum reachable position and/or orientation along at least one translational and/or rotational degree of freedom of the optical module in step g), for example during the measurement via the primary sensor, and/or for the optical module to be situated in at least one maximum reachable position and/or orientation along at least one translational and/or rotational degree of freedom of the optical module in step g), for example during the measurement via the primary sensor. This can help facilitate a check of the final adjustment, since the measurement signal of the primary sensor is captured during step g) for substantially the entire adjustment range of the optical module, for example also the maximum reachable positions and/or orientations. In step g), the optical module can be moved out of the basic position and/or basic orientation of the optical module in the direction of at least one maximum reachable position and/or orientation along at least one translational degree of freedom and/or at least one rotational degree of freedom of the optical module. Performing the measurement in step g) can comprise the capture and/or storage of at least a portion of the measurement signal, for example the entire measurement signal, of the primary sensor. The optical module can be moved along at least one, such as at least two, for example at least three, translational degrees of freedom and/or at least one, such as at least two, for example at least three, rotational degrees of freedom of the optical module into the maximum reachable positions and/or orientation along the respective degree of freedom in step g), for example during the measurement via the primary sensor. In this case, provision can be made for the optical module to be moved at least temporarily, for example substantially completely, in succession and/or at the same time along at least two translational and/or rotational degrees of freedom.

One embodiment of the method provides for a measurement to be performed via at least one secondary sensor in step b) and/or step g), for the secondary sensor to be configured to detect a change in the position and/or the orientation of at least one part of the manipulator, the position and/or orientation of at least one part of the manipulator, a change in the position and/or the orientation of the optical module and/or the position and/or the orientation of the optical module, and for, optionally, the position and/or orientation of the optical module to be controlled and/or regulated in step b) and/or step g) on the basis of the measurement of the secondary sensor. By using a sensor other than the primary sensor for controlling or regulating the position and/or orientation of the optical module, precise control or regulation, often any functional control or regulation at all, of the position and/or orientation of the optical module is achieved since the primary sensor is not yet sufficiently adjusted and does not provide a measurement signal, or its measurement signal cannot be used for precise control or regulation of the position and/or orientation of the optical module. The primary sensor and the secondary sensor are for example different sensors, the primary sensor and the secondary sensor function independently of each other, and/or the primary sensor has a higher measurement resolution than the secondary sensor. The secondary sensor thus can allow a separate measurement from the primary sensor. The secondary sensor can be arranged on the at least one manipulator. The change in the position and/or the orientation of at least one part of the manipulator, the position and/or orientation of at least one part of the manipulator, the change in the position and/or the orientation of the optical module and/or the position and/or the orientation of the optical module can be detected in step b) and/or step g) via the secondary sensor. In turn, the change in the position and/or orientation of the optical module and/or the position and/or orientation of the optical module can be determined on the basis of the detected change in the position and/or orientation of at least one part of the manipulator and/or the detected position and/or orientation of at least one part of the manipulator. Performing the measurement in step b) and/or step g) can comprise the capture and/or storage of at least a portion of the measurement signal of the secondary sensor.

One embodiment of the method provides for the method to comprise the following step: h) checking the final adjustment performed in step c), a measurement being performed using the primary sensor, and the optical module being moved, for example relative to the primary sensor. This can help ensure that the final adjustment performed in step c) has positioned the primary sensor in a best possible position and/or orientation. In step h), the final adjustment of the majority of the optical modules, for example of each optical module, of a projection exposure apparatus can be checked. This can help allow for acceptance of the respective primary sensors for all optical modules of a projection exposure apparatus. Step h) can be implemented after step a), step b), step c), step d), step e), step f) and/or step g). In step h), the optical module can be moved via at least one manipulator, for example of a projection exposure apparatus. The at least one manipulator can be at least one manipulator arranged in a projection exposure apparatus and/or manipulator provided for manipulation of the optical module and/or of the primary sensor, for example during the operation of the projection exposure apparatus. Therefore, additional equipment can be omitted or at least the equipment can be reduced in order to move the optical module. Provision can be made for the primary sensor to detect the change in the position and/or the orientation of the optical module and/or the measurement reference in step h) and/or for the primary sensor to detect the position and/or the orientation of the optical module and/or the measurement reference in step h). The optical module can be moved while the measurement is performed in step h) via the primary sensor. Provision can be made for the optical module to be moved, for example substantially completely, along at least one, such as at least two, for example at least three, translational degrees of freedom and/or at least one, such as at least two, for example at least three, rotational degrees of freedom of the optical module and/or the primary sensor in step h), optionally during the measurement and/or in a manner mounted in a projection exposure apparatus. This facilitates a check of the final position and/or final orientation of the primary sensor since the measurement signal is captured during step h) for substantially the entire adjustment range of the optical module. Provision can be made for the optical module to be moved at least temporarily, for example substantially completely, in succession and/or at the same time along at least two translational and/or rotational degrees of freedom.

One embodiment of the method provides for the optical module to be moved in the direction of at least one maximum reachable position and/or orientation along at least one translational and/or rotational degree of freedom of the optical module in step h), for example during the measurement via the primary sensor, and/or for the optical module to be situated in at least one maximum reachable position and/or orientation along at least one translational and/or rotational degree of freedom of the optical module in step h), for example during the measurement via the primary sensor. This can help facilitate a check of the final adjustment, since the measurement signal of the primary sensor is captured during step h) for substantially the entire adjustment range of the optical module, for example also the maximum reachable positions and/or orientations. In step h), the optical module can be moved out of the basic position and/or basic orientation of the optical module in the direction of at least one maximum reachable position and/or orientation along at least one translational degree of freedom and/or at least one rotational degree of freedom of the optical module. Performing the measurement in step h) can comprise the capture and/or storage of at least a portion of the measurement signal, for example the entire measurement signal, of the primary sensor. The optical module can be moved along at least one, such as at least two, for example at least three, translational degrees of freedom and/or at least one, such as at least two, for example at least three, rotational degrees of freedom of the optical module into the maximum reachable positions and/or orientation along the respective degree of freedom in step h), for example during the measurement via the primary sensor. In this case, provision can be made for the optical module to be moved at least temporarily, for example substantially completely, in succession and/or at the same time along at least two translational and/or rotational degrees of freedom.

One embodiment of the method provides for the position and/or orientation of the optical module to be controlled and/or regulated in step h) on the basis of the measurement of the primary sensor. This can help allow a check as to whether the primary sensor adjustment has achieved the desired result. Moreover, it is possible to check whether the primary sensor has a malfunction or has been connected incorrectly. In contrast to step g), the position and/or orientation of the optical module can be not controlled and/or regulated on the basis of the measurement of the secondary sensor in step h).

One embodiment of the method provides for the optical module and/or the primary sensor to be arranged at least temporarily on at least one frame, for example of a projection exposure apparatus, in step b), step c), step d), step e), step f), step g) and/or step h). The frame can firstly form a reliable reference for determination of the position and/or orientation of the components of the projection exposure apparatus and secondly absorb the static loads, which for example originate from the gravitational force, and the dynamic loads, for example from positioning and/or orientation movements of the components of the projection exposure apparatus. The at least one frame of a projection exposure apparatus can be the force frame and/or the sensor frame of a projection exposure apparatus. The optical module and/or the primary sensor can be arranged substantially permanently on at least one frame, for example of a projection exposure apparatus, in step b), step c), step d), step e), step f), step g) and/or step h).

In an alternative to that or in addition, the optical module and/or the sensor can be mounted in a projection exposure apparatus in step b), step c), step d), step e), step f), step g) and/or step h).

In an alternative or in addition to the method described above, the method described below can be performed in order to facilitate a precise and simple adjustment of a primary sensor, for example relative to a measurement reference:

A method for assigning a primary sensor for a projection exposure apparatus to a measurement reference, comprising the following steps:
aa) providing a primary sensor and a measurement reference,
bb) arranging the primary sensor and/or the measurement reference in a respective target position and/or target orientation,
cc) performing a measurement using the primary sensor vis-à-vis the measurement reference and/or performing a precise measurement of the primary sensor and/or the measurement reference, and
dd) assigning the primary sensor to the measurement reference.

For example, the primary sensor and/or the measurement reference provided in step aa) can be the at least one sensor provided in step a) and/or the at least one measurement reference provided in step a).

In step bb), the primary sensor and/or the measurement reference can be arranged in a test stand. In this test stand, the primary sensor and the measurement reference are arranged in the respective target position and/or target orientation, such as relative to each other. The test stand facilitates the arrangement in the respective target position and/or target orientation.

In step cc), at least one piece of information about the primary sensor and/or the measurement reference is determined during the measurement performed and/or the precise measurement performed; for example, the offset between the primary sensor and the measurement reference is determined, the offset of the primary sensor and/or the measurement reference from the respective target position and/or target orientation is determined, and/or at least one piece of geometry information of the primary sensor and/or the measurement reference is determined. In step cc), the primary sensor and/or the measurement reference is arranged in the respective target position and/or target orientation, such as in the test stand.

The assignment in step dd) achieves a consistent logical assignment of primary sensor to measurement reference for a subsequent adjustment or arrangement of the primary sensor and/or the measurement reference; this assignment is optionally also retained for further subsequent steps. Each primary sensor thus has its assigned measurement reference. The at least one piece of information obtained in step cc) can be used for further steps, for example the adjustment of the primary sensor and/or the measurement reference. An initial adjustment of the primary sensor can optionally be omitted using this at least one piece of information since the primary sensor and/or the measurement reference can be arranged directly in the best possible position and/or orientation on the basis of the at least one piece of information obtained in step cc).

The method for assigning a primary sensor for a projection exposure apparatus to a measurement reference may also comprise further steps, for example the following step:
ee) determining a final position and/or final orientation of the primary sensor and/or the measurement reference using the measurement and/or precise measurement performed in step cc) and/or determining a final alignment element using the measurement and/or precise measurement performed in step cc). The final alignment element determined in step ee) can be arranged on the primary sensor and/or on at least one frame of a projection exposure apparatus, for example the sensor frame, and has for example a geometry adapted to the final position and/or final orientation of the primary sensor. The determination in step ee) can be implemented using a virtual model, can comprise at least one piece of geometry information of the optical module, the primary sensor, the measurement reference, at least one frame of a projection exposure apparatus and/or at least one connecting element of a projection exposure apparatus. In an alternative to that or in addition, the virtual model can comprise the at least one piece of information determined in step cc). In an alternative to that or in addition, the virtual model can comprise the position and/or the orientation of the measurement reference relative to an optical module, the position and/or orientation of the optical module relative to at least one frame of a projection exposure apparatus, such as a first frame of a projection exposure apparatus, for example the force frame of a projection exposure apparatus, the position and/or orientation of a sensor receptacle relative to at least one frame of a projection exposure apparatus, such as a second frame of a projection exposure apparatus, for example the sensor frame of a projection exposure apparatus, and/or the position and/or orientation of the primary sensor relative to the measurement reference. For example, the sensor receptacle is arranged on the sensor frame, and/or the measurement reference is arranged on the optical module. The optical module, the at least one frame of a projection exposure apparatus, for example the sensor frame and/or the force frame, the at least one connecting element of a projection exposure apparatus and/or the sensor receptacle can be provided here to be connected to the primary sensor and/or the measurement reference.

The method for assigning a primary sensor for a projection exposure apparatus to a measurement reference can moreover comprise the following step: ff) performing a final adjustment of the primary sensor, the primary sensor and/or the measurement reference optionally being arranged in the respective final position and/or the final orientation and/or the final alignment element optionally being arranged on the primary sensor. Step ff) can be implemented after step ee).

The aforementioned problem is also solved by a projection exposure apparatus comprising: at least one primary sensor and at least one optical module, wherein the primary sensor is adjusted relative to the optical module as per a method according to the disclosure. This can yield a projection exposure apparatus comprising a primary sensor that is aligned in the best possible way.

Further features and aspects of the methods and the projection exposure apparatus emerge from the following description of exemplary embodiments, with reference to the attached drawings.

### BRIEF DESCRIPTION OF THE DRAWINGS

In the drawings:

FIG. 1 shows the basic structure of a projection exposure apparatus;

FIG. 2 shows an optical module, with multiple measurement references arranged on the optical module, and multiple primary sensors in a perspective view;

FIG. 3 shows a detail of the optical module from FIG. 2 and one of the primary sensors from FIG. 2 in a perspective view;

FIG. 4 shows the optical module from FIG. 2 mounted in a projection exposure apparatus in a side view; and

FIG. 5 shows a flowchart of a method for adjusting at least one primary sensor.

### DETAILED DESCRIPTION

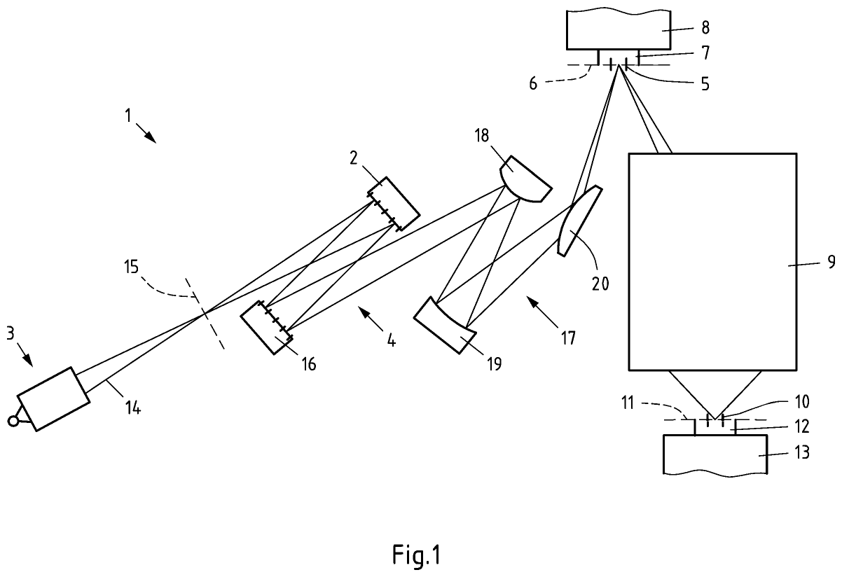

FIG. 1 shows, by way of example, the basic structure of a microlithographic EUV projection exposure apparatus 1, for which the disclosed method is used. An illumination system of the projection exposure apparatus 1 has, besides a radiation source 3, an illumination optical unit 4 for illuminating an object field 5 in an object plane 6. EUV radiation 14 in the form of exposure radiation created by the radiation source 3 is aligned via a collector, which is integrated in the radiation source 3, in such a way that it passes through an intermediate focus in the region of an intermediate focal plane 15 before it is incident on an optical module in the form of a field facet mirror 2. Downstream of the field facet mirror 2, the EUV radiation 14 is reflected by an optical module in the form of a pupil facet mirror 16. Field facets of the field facet mirror 2 are imaged into the object field 5 with the aid of the pupil facet mirror 16 and an optical assembly 17 having multiple optical modules, with the optical modules each having at least one mirror 18, 19, 20. A reticle 7 arranged in the object field 5 and held by a schematically depicted reticle holder 8 is illuminated. A merely schematically depicted projection optical unit 9 serves for imaging the object field 5 into an image field 10 in an image plane 11. A structure on the reticle 7 is imaged onto a light-sensitive layer of a wafer 12, which is arranged in the region of the image field 10 in the image plane 11 and is held by a wafer holder 13, which is likewise depicted in sections. The radiation source 3 can emit exposure radiation, such as in a wavelength range between 5 nm and 30 nm, for example at 13.5 nm.

The disclosed method can likewise be used for a DUV apparatus, which is not depicted. In principle, a DUV apparatus can be constructed like the above-described EUV projection exposure apparatus 1, wherein mirrors and lens elements can be used as optical elements in a DUV projection exposure apparatus, and the radiation source of a DUV projection exposure apparatus emits exposure radiation in a wavelength range from 150 nm to 400 nm.

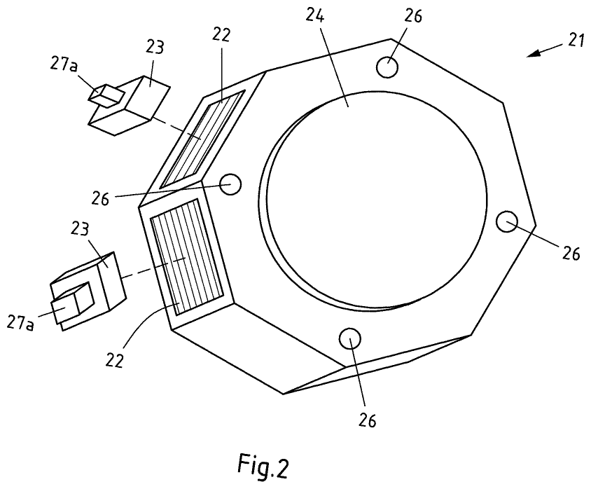

FIG. 2 shows an optical module 21, with multiple measurement references 22 arranged on the optical module 21, and multiple primary sensors 23 in a perspective view. The optical module 21 can be one of the above-described optical modules, wherein the optical module 21 can for example be mounted in the above-described projection exposure apparatus 1. The optical module 21 shown in FIG. 2 comprises a mirror 24 as an optical element, the mirror 24 being provided for guiding exposure radiation, for example EUV radiation 14 should the optical module 21 be used in a EUV projection exposure apparatus 1.

Multiple measurement references 22 are arranged on, for example adhesively bonded to, the sides of the optical module 21. In this case, the measurement references 22 are designed as measuring grids. The measurement references 22 in each case interact with a primary sensor 23, a primary sensor 23 being arranged opposite a measurement reference 22 in each case. Only two measurement references 22 and two primary sensors 23 are shown in FIG. 2; however, more or fewer measurement references 22 and primary sensors 23 can also be provided, for example six measurement references 22 and six primary sensors 23 per optical module 21. The primary sensors 23 are configured to detect a change in the position and/or the orientation of the measurement reference 22 and thus of the optical module 21 and/or are configured to detect the position and/or the orientation of the measurement reference 22 and thus of the optical module 21. The measurement signals captured by the primary sensors 23 allow a precise correction of aberrations to be achieved during the operation of the projection exposure apparatus 1, by changing the position and/or the orientation of the optical module 21.

The projection exposure apparatus 1 comprises multiple manipulators 25 for changing the position and/or the orientation of the optical module 21, i.e. moving the optical module 21. In this case, multiple schematically shown connecting elements 26 are provided in the optical module 21 shown in FIG. 2 for interaction with the manipulators 25.

Respectively initial alignment elements 27a are arranged on the primary sensors 23 shown in FIG. 2 in order to arrange each of the primary sensors 23 in an initial position and an initial orientation. The respective initial alignment element 27a is arranged on a frame of the projection exposure apparatus 1 in each case. However, the frame is not shown in FIG. 2. In the initial position and initial orientation, the respective primary sensor 23 is arranged in such a way relative to the assigned measurement reference 22 that the primary sensor 23 can be used to capture a measurement of the position and/or the orientation or the change in the position and/or the orientation of the measurement reference 22 or the optical module 21. For example, the initial position and the initial orientation are determined using a virtual model, wherein this virtual model comprises the pieces of geometry information of multiple components of the projection exposure apparatus 1, for example at least one piece of geometry information of the optical module 21, the primary sensor 23, the measurement reference 22, at least one frame of the projection exposure apparatus 1 and/or at least one connecting element 26 of the projection exposure apparatus 1. These pieces of geometry information can be determined in advance by a measurement, for example precise measurement, of the corresponding components of the projection exposure apparatus 1 via a coordinate measuring machine. Then, the respective initial alignment element 27a is determined on the basis of the determined initial position and initial orientation. However, in the initial position and initial orientation, the primary sensor 23 is generally not yet aligned to the best possible extent. Therefore, a further adjustment step is performed, as explained in connection with the following figures.

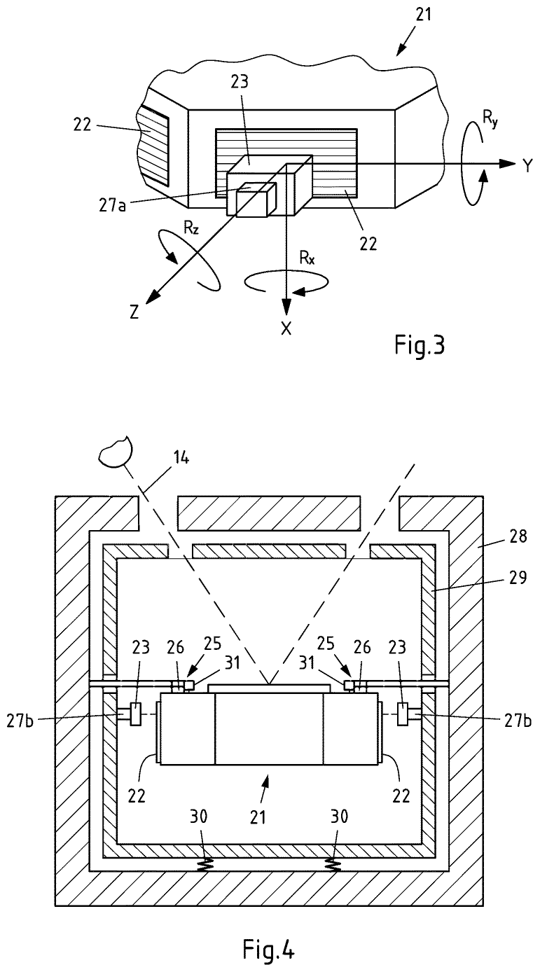

FIG. 3 shows a detail of the optical module 21 from FIG. 2 and one of the primary sensors 23 from FIG. 2 in a perspective view. Moreover, the translational degrees of freedom X, Y, Z and the rotational degrees of freedom R_{X}, R_{Y}, R_{Z} of the optical module 21 are plotted, along which the optical module 21 can be moved, for example via the manipulators 25. In an alternative to that or in addition, the primary sensor 23 could also be moved, but a movement of the optical module 21 will be concentrated on below.

In order to determine the best possible position and orientation of the primary sensor 23, the optical module 21 is moved, for example substantially completely, along at least one translational degree of freedom X, Y, Z and/or at least one rotational degree of freedom R_{X}, R_{Y}, R_{Z} of the optical module 21, and a measurement is performed in the meantime via the primary sensor 23. In so doing, the measurement signal of the primary sensor 23 during the measurement is captured. For example, the optical module 21 can be initially displaced along the Z-axis (movement along the translational degree of freedom Z), then rotated about the X-axis (movement along the rotational degree of freedom R_{X}) and subsequently rotated about the Y-axis (movement along the rotational degree of freedom R_{Y}). Which movements are carried out depends inter alia on the type of primary sensor 23 used; for example, the extent to which the measurement signal of the primary sensor 23 changes in the event of a movement of the primary sensor 23 in the direction of one of the degrees of freedom X, Y, Z, R_{X}, R_{Y}, R_{Z} is decisive, in other words it depends on the measurement sensitivity of the primary sensor 23. If there can be a change, for example a significant change, in the measurement signal of the primary sensor 23 during a movement of the optical module 21 in the direction of a specific degree of freedom X, Y, Z, R_{X}, R_{Y}, R_{Z}, then the direction of this degree of freedom X, Y, Z, R_{X}, R_{Y}, R_{Z} lends itself to the movement of the optical module 21 during the measurement. This is because the primary sensor 23 should for example be arranged in the position and/or orientation in which the measurement signal, for example the amplitude of the measurement signal, of the primary sensor 23 is as high as reasonably possible, for example substantially at a maximum, when the optical module 21 is in its basic position and/or basic orientation. In some cases, an optimal adjustment can additionally involve the phase and/or the offset of the measurement signal to be located within a tolerance range. Then, the final position and final orientation of the primary sensor 23 can be determined on the basis of this measurement, on which basis a final alignment element 27b can in turn be determined for the primary sensor 23. Determination of the final position and final orientation can for example be implemented by way of a graphical evaluation of the captured measurement signal of the primary sensor 23, for example the amplitude, the phase and/or the offset of the measurement signal.

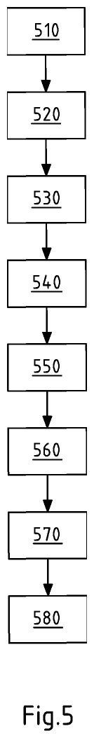

FIG. 4 shows the optical module 21 from FIG. 2 mounted in the projection exposure apparatus 1 in a side view. In this case, the optical module 21 is arranged on a frame of the projection exposure apparatus 1, the so-called force frame 28. The optical module 21 can be moved via the manipulators 25, as already explained. The primary sensor 23 is arranged on another frame of the projection exposure apparatus 1, the so-called sensor frame 29. The sensor frame 29 is mechanically largely decoupled from the surroundings, for example the force frame 28, and this is indicated by the plotted decoupling elements 30. The depicted arrangement of the optical module 21 on the force frame 28 and the configuration of the force frame 28 and the sensor frame 29 are shown purely schematically here.

In FIG. 4, the primary sensors 23 are already arranged on the sensor frame 29 via a respective final alignment element 27b. To this end, the initial alignment element 27a was switched with the final alignment element 27b. The adjustment of the primary sensor 23 can also be checked in order to ensure that the adjustment of the primary sensor 23 has delivered the desired result.

Firstly, in order to check the adjustment, the optical module 21 can be moved along at least one degree of freedom X, Y, Z, R_{X}, R_{Y}, R_{Z}, for example along all six degrees of freedom X, Y, Z, R_{X}, R_{Y}, R_{Z}, into the respectively maximum reachable position and/or orientation, and a measurement can be performed at the same time using the primary sensor 23. The measurement of the primary sensor 23 can then be used to check whether the performed adjustment of the primary sensor 23 has yielded the desired result. A measurement is performed via at least one secondary sensor 31 during the check of the adjustment, optionally also while the measurement via the primary sensor 23 is taking place during the movement of the optical module 21, which is described in connection with FIG. 3. Two secondary sensors 31 are shown in FIG. 2; however, more or fewer secondary sensors 31 can also be provided. In this case, the secondary sensors 31 are arranged on the manipulators 25. Where the maximum reachable position and/or orientation is located along the respective degree of freedom depends for example on the maximum possible travel of the manipulators 25 and/or the clear space between the optical module 21 and another component of the projection exposure apparatus 1 in the direction of the respective degree of freedom X, Y, Z, R_{X}, R_{Y}, R_{Z}. Then, a change in the position and/or the orientation of at least a part of the manipulator 25 is detected and/or the position and/or orientation of at least a part of the manipulator 25 is detected via the secondary sensors 31 during the movement of the optical module 21. Then, this is used as a basis to regulate the position and/or orientation of the optical module 21 during the movement of the optical module 21. By using the secondary sensors 31, precise control and/or regulation, often any functional control and/or regulation at all, of the position and/or orientation of the optical module 21 is achieved since the primary sensor 23 is not yet sufficiently adjusted and does not provide a measurement signal, or its measurement signal cannot be used for precise control and/or regulation of the position and/or orientation of the optical module 23. If a measurement is performed using both the primary sensor 23 and the secondary sensor 31, then a comparison of the measurement signals from the two sensors moreover makes it possible to check that, for example, there is no malfunction of the primary sensors 23 or has been incorrect connection of the primary sensors 23, which could otherwise lead to a collision of the optical module 21 with other components of the projection exposure apparatus 1 and would thus damage the optical module 21 or the other components.

In order to check the adjustment in an alternative to that or in addition, the optical module 21 can be moved along at least one degree of freedom X, Y, Z, R_{X}, R_{Y}, R_{Z}, for example along all six degrees of freedom X, Y, Z, R_{X}, R_{Y}, R_{Z}, into the respectively maximum reachable position, and a measurement can be performed using the primary sensors 23 at the same time. In this case, however, the position and/or orientation of the optical module 21 during the movement is regulated on the basis of the measurement via the primary sensor 23. This lends itself for example if there initially was a check in which the position and/or orientation of the optical module 21 was regulated on the basis of the measurement of the secondary sensor 31. A corresponding check can be carried out for all optical modules 21 of the projection exposure apparatus 1, and so all optical modules of the projection exposure apparatus 1 are moved accordingly and a measurement is implemented via the respective primary sensors 23.

FIG. 5 shows a flowchart of a method for adjusting at least one primary sensor 23, as has already been described in connection with FIGS. 1 to 4. For example, the method can be summarized as follows:
providing at least one primary sensor 23 and at least one optical module 21 for a projection exposure apparatus 1 (step 510),
determining an initial position and/or an initial orientation of the primary sensor 23 and/or determining at least one initial alignment element 27a for the primary sensor 23 (step 520),
performing an initial adjustment of the primary sensor 23 (step 530),
performing a measurement using the primary sensor 23 (step 540),
determining the final position and/or the final orientation of the primary sensor 23 and/or determining at least one final alignment element 27b for the primary sensor 23 (step 550),
performing a final adjustment of the primary sensor 23 (step 560),
checking the final adjustment, wherein a measurement is performed via the primary sensor 23, and during this time the position and/or orientation of the optical module 21 is regulated on the basis of the measurement of at least one secondary sensor 31 (step 570), and
checking the final adjustment, wherein a measurement is performed via the primary sensor 23, and during this time the position and/or orientation of the optical module 21 is regulated on the basis of the measurement of the primary sensor 23 (step 580).

### LIST OF REFERENCE SIGNS

1 Projection exposure apparatus
2 Field facet mirror
3 Radiation source
4 Illumination optical unit
5 Object field
6 Object plane
7 Reticle
8 Reticle holder
9 Projection optical unit
10 Image field
11 Image plane
12 Wafer
13 Wafer holder
14 Radiation
15 Intermediate focal plane
16 Pupil facet mirror
17 Optical assembly
18 Mirror
19 Mirror
20 Mirror
21 Optical module
22 Measurement reference
23 Primary sensor
24 Mirror
25 Manipulator
26 Connecting element
27a Initial alignment element
27b Final alignment element
28 Force frame
29 Sensor frame
30 Decoupling element
31 Secondary sensor
R_{X}, R_{Y}, R_{Z} Rotational degree of freedom
X, Y, Z Translational degree of freedom

What is claimed is:

1. A method, comprising:
a) providing a primary sensor and an optical module for a projection exposure apparatus, wherein a measurement reference is supported by the optical module, and wherein the primary sensor is configured to detect: i) a change in a position of the optical module, a change in a position of the measurement reference, a change in an orientation of the optical module and/or a change in an orientation of the measurement reference; and/or ii) the position of the optical module, the position of the measurement reference, the orientation of the optical module, and/or the orientation of the measurement reference;
b) performing a measurement using the primary sensor comprising, wherein during the measurement: i) the optical module is moved relative to the primary sensor; and/or ii) the primary sensor is moved relative to the optical module; and
c) performing a final adjustment of the primary sensor using the measurement performed in b), wherein the primary sensor is in a final position and/or a final orientation.

2. The method of claim 1, wherein b) comprises using a manipulator to move the optical module and/or the primary sensor.

3. The method of claim 1, wherein b) comprises moving the optical module along a translational and/or rotational degree of freedom of the optical module, and/or wherein b) comprises moving the primary sensor along a translational and/or rotational degree of freedom the primary sensor.

4. The method of claim 1, further comprising:
d) determining the final position and/or the final orientation of the primary sensor and/or determining a final alignment element for the primary sensor.

5. The method of claim 4, wherein d) comprises determining the final position and/or the final orientation of the primary sensor using the measurement performed in b), and/or wherein d) comprises determining the final alignment element using the measurement performed in b).

6. The method of claim 1, further comprising:
e) determining an initial position and/or an initial orientation of the primary sensor and/or determining at least one initial alignment element for the primary sensor,
wherein the primary sensor in the initial position and/or the initial orientation being able to detect a change in the position and/or the orientation of the optical module, and/or wherein the measurement reference and/or the primary sensor in the initial position and/or the initial orientation being able to detect the position and/or the orientation of the optical module and/or the measurement reference.

7. The method of claim 6, wherein e) comprises determining the initial position and/or the initial orientation of the primary sensor using geometry information of the optical module, the primary sensor, the measurement reference, at least one frame of a projection exposure apparatus and/or at least one connecting element of a projection exposure apparatus, and/or wherein e) comprises determining the initial alignment element using geometry information of the optical module, the primary sensor, the measurement reference, at least one frame of a projection exposure apparatus and/or at least one connecting element of a projection exposure apparatus.

8. The method of claim 6, wherein e) comprises determining the initial position and/or the initial orientation of the primary sensor using a virtual model, and/or wherein e) comprises determining the initial alignment element using a virtual model.

9. The method of claim 1, further comprising:
f) performing an initial adjustment of the primary sensor,
wherein the primary sensor is arranged in the initial position and/or the initial orientation, and/or wherein the initial alignment element is supported by the primary sensor.

10. The method of claim 1, wherein c) comprises: i) modifying the position and/or the orientation of the primary sensor; ii) arranging the final alignment element on the primary sensor; and/or ii) switching the initial alignment element with the final alignment element.

11. The method of claim 1, further comprising:
g) checking the final adjustment performed in c),
wherein a measurement is performed using the primary sensor, and the optical module is moved.

12. The method of claim 11, wherein g) comprises moving the optical module is moved in a direction of a maximum reachable position and/or orientation along a translational and/or rotational degree of freedom (X, Y, Z, R_{X}, R_{Y}, R_{Z}) of the optical module, and/or wherein g) comprises situating the optical module in a maximum reachable position and/or orientation along a translational and/or rotational degree of freedom of the optical module.

13. The method of claim 1, wherein b) and/or g) comprises performing a measurement using a secondary sensor configured to detect: i) a change in the position and/or the orientation of at least one part of a manipulator; ii) the position and/or orientation of at least one part of the manipulator; iii) a change in the position and/or the orientation of the optical module; iv) the position and/or the orientation of the optical module.

14. The method of claim 1, further comprising:
h) checking the final adjustment performed in c),
wherein a measurement is performed using the primary sensor, and the optical module is moved.

15. The method of claim 14, wherein h) comprises moving the optical module in the direction of a maximum reachable position and/or orientation along a translational and/or rotational degree of freedom of the optical module, and/or wherein h) comprises situating the optical module in a maximum reachable position and/or orientation along a translational and/or rotational degree of freedom of the optical module.

16. The method of claim 14, wherein h) comprises controlling and/or regulating the position and/or orientation of the optical module based on the measurement of the primary sensor.

17. The method of claim 1, wherein b) or c) comprises at least temporarily arranging the optical module and/or the primary sensor on a frame.

18. One or more machine-readable hardware storage devices comprising instructions that are executable by one or more processing devices to perform operations comprising the method of claim 1.

19. A system, comprising:
one or more processing devices; and
one or more machine-readable hardware storage devices comprising instructions that are executable by the one or more processing devices to perform operations comprising the method of claim 1.

20. The system of claim 19, further comprising the primary sensor and the optical module.
